(19) United States
(12) Patent Application Publication
(10) Pub. No.: US 2026/0059864 A1
(43) Pub. Date: Feb. 26, 2026

(54) HIGH VOLTAGE SEMICONDUCTOR DEVICE WITH ELECTROSTATIC DISCHARGE SELF-PROTECTION STRUCTURE

(71) Applicant: SK keyfoundry Inc., Cheongju-si (KR)

(72) Inventors: Youngbae KIM, Sejong-si (KR); Eunkyung PARK, Cheongju-si (KR); Heehwan JI, Daejeon-si (KR)

(73) Assignee: SK keyfoundry Inc., Cheongju-si (KR)

(21) Appl. No.: 19/038,362

(22) Filed: Jan. 27, 2025

(30) Foreign Application Priority Data
Aug. 23, 2024 (KR) 10-2024-0113369
Aug. 28, 2024 (KR) 10-2024-0115619

(51) Int. Cl. H10D 89/60; H10D 62/10; H10D 62/17

(52) U.S. Cl. CPC H10D 89/713; H10D 62/106; H10D 62/393

(57) ABSTRACT

A semiconductor device includes a PN diode; a drain region; a source region; a gate region formed between the drain region and the source region; a first p-type guard ring and a NP guard ring surrounding the PN diode. The NP guard ring includes a n-type guard ring and a second p-type guard ring; a drain Silicon Controlled Rectified (SCR) formed in the drain region and including a highly-doped n-type drain region (N+ drain region) and a highly-doped p-type drain region (P+ drain region), the drain SCR electrically connected to a high voltage; a first guard ring SCR formed in the first p-type guard ring and including a first highly doped n-type region (first N+ region) and a first highly doped p-type region (first P+ region); and a second guard ring SCR formed in the NP guard ring and including a second N+ region and a second P+ region.

### CROSS-REFERENCE TO RELATED APPLICATION

The application claims the benefit under 35 USC 119(a) of Korean Patent Application Nos. 10-2024-0113369, filed on Aug. 23, 2024, and 10-2024-0115619, filed on Aug. 28, 2024, in the Korean Intellectual Property Office, the entire disclosures of which are incorporated herein by reference for all purposes.

### BACKGROUND

### 1. Field

Embodiments of the present disclosure relate to a high-voltage semiconductor device with an Electrostatic Discharge (ESD) self-protection structure based on a silicon-controlled rectifier (SCR).

### 2. Description of the Background

High voltage (HV) semiconductor devices over 600V comprising a high-side gate driver IC and a low-side gate driver IC have been widely used for motor drivers, which may require a bootstrap diode and a level shifter to provide a high voltage around 600V or 1200V for driving power MOSFETs or discrete devices. When manufacturing the HV semiconductor device comprising the high-side gate driver IC and the low-side gate driver IC, a very high ESD current may flow into the HV device. An HV semiconductor device structure may be desired to withstand the very high ESD current. To improve ESD performance, several methods have been proposed. However, those structures may require a large area and complicated HV semiconductor device to bypass the very high ESD current.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes a PN diode formed on a p-type semiconductor substrate; a drain region and a source region formed on the p-type semiconductor substrate; a gate region formed between the drain region and the source region; a first p-type guard ring and a NP guard ring surrounding the PN diode. The NP guard ring includes a n-type guard ring and a second p-type guard ring; a drain Silicon Controlled Rectified (SCR) formed in the drain region and including a highly-doped n-type drain region (N+ drain region) and a highly-doped p-type drain region (P+ drain region), the drain SCR electrically connected to a high voltage; a first guard ring SCR formed in the first p-type guard ring and including a first highly doped n-type region (first N+ region) and a first highly doped p-type region (first P+ region); and a second guard ring SCR formed in the NP guard ring and including a second N+ region and a second P+ region. The first guard ring SCR and the second guard ring SCR are electrically connected to a ground voltage.

The high voltage may be 600V or more.

The first p-type guard ring may have a cross-sectional area greater than a cross-sectional area of the second p-type guard ring.

The PN diode may include a first n-type buried layer (NBL) formed on the p-type semiconductor substrate; a deep p-type well region (DPW) formed on the first NBL; a P+ base region and an N+ collector region electrically connected to an anode electrode; and an N+ emitter region electrically connected to the source region through an emitter electrode.

The semiconductor device may further include an n-type semiconductor region formed on the p-type semiconductor substrate; a first n-type well region (NW) enclosing the drain SCR; a field plate electrically connected to the drain SCR and formed on a field oxide film (FOX); a p-type top layer (P-TOP) formed in the n-type semiconductor region; a p-type body region (P-body) electrically connected to the P-TOP; a highly doped p-type body region (P+ body region) formed in the P-body; a gate electrode overlapped with the P-body; and a highly doped n-type source region (N+ source region) formed in the n-type semiconductor region.

The semiconductor device may further include a first p-type buried layer (first PBL) formed in the first p-type guard ring and formed below the first N+ region and the first P+ region; a second NBL formed in the NP guard ring and formed below the second N+ region; and a second PBL formed in the NP guard ring and formed below the second P+ region. The second N+ region and the second P+ region may be formed separately from each other by a field oxide film (FOX).

The semiconductor device may further include a body SCR formed in the gate region and comprising a highly doped p-type body region (P+ body region) and a highly doped n-type body region (N+ body region), the body SCR electrically connected to the ground voltage.

The P+ body region may be formed closer to the drain region than the N+ body region.

In another general aspect, a semiconductor device includes a PN diode formed on a p-type semiconductor substrate; a drain region and a source region formed on the p-type semiconductor substrate; a gate region formed between the drain region and the source region; a first p-type guard ring and a NP guard ring surrounding the PN diode, the NP guard ring comprising a n-type guard ring and a second p-type guard ring; a drain Silicon Controlled Rectified (SCR) formed in the drain region and comprising a highly-doped n-type drain region (N+ drain region) and a highly-doped p-type drain region (P+ drain region), the drain SCR electrically connected to a high voltage; a body SCR formed in the gate region and comprising a highly-doped p-type body region (P+ body region) and a highly-doped n-type body region (N+ body region), the body SCR electrically connected to a ground voltage; a first guard ring SCR formed in the first p-type guard ring and comprising a first highly doped n-type region (first N+ region) and a first highly doped p-type region (first P+ region); and a second guard ring SCR formed in the NP guard ring and comprising a second N+ region and a second P+ region, wherein the first guard ring SCR and the second guard ring SCR are electrically connected to the ground voltage.

The high voltage may be 600V or more.

The first p-type guard ring may have a cross-sectional area greater than a cross-sectional area of the second p-type guard ring.

The P+ body region may be formed closer to the drain region than the N+ body region.

The PN diode may include a first n-type buried layer (NBL) formed on the p-type semiconductor substrate; a deep p-type well region (DPW) formed on the first NBL; a P+ base region and an N+ collector region electrically connected to an anode electrode; and an N+ emitter region electrically connected to the source region through an emitter electrode.

The semiconductor device may further include an n-type semiconductor region formed on the p-type semiconductor substrate; a first n-type well region (NW) enclosing the drain SCR; and a field plate electrically connected to the drain SCR and formed on a field oxide film (FOX); a p-type top layer (P-TOP) formed in the n-type semiconductor region; a p-type body region (P-body) electrically connected to the P-TOP; a highly doped p-type body region (P+ body region) formed in the P-body; and a gate electrode overlapped with the P-body; and a highly doped n-type source region (N+ source region) formed in the n-type semiconductor region.

The semiconductor device may further include a first p-type buried layer (first PBL) formed in the first p-type guard ring and formed below the first N+ region and the first P+ region; a second NBL formed in the NP guard ring and formed below the second N+ region; and a second PBL formed in the NP guard ring and formed below the second P+ region, wherein the second N+ region and the second P+ region are formed separately from each other by a field oxide film (FOX).

In another general aspect, a semiconductor device configured to operate in low and high voltages, includes a drain region, a gate region, a source region, a first PNP guard ring, a PN diode, and a second PNP guard ring sequentially formed in order on a p-type semiconductor substrate; a drain Silicon Controlled Rectified (SCR), formed in the drain region, comprising a highly-doped n-type drain region (N+ drain region) and a highly-doped p-type drain region (P+ drain region), the drain SCR electrically connected to a high voltage; a first guard ring SCR, formed in the first PNP guard ring, comprising a first highly doped n-type region (first N+ region) and a first highly doped p-type region (first P+ region); and a second guard ring SCR formed, adjacent to the first guard ring SCR, in the first PNP guard ring, the second guard ring SCR comprising a second N+ region and a second P+ region. The first guard ring SCR and the second guard ring SCR are electrically connected to a ground voltage. The PN diode includes a first n-type buried layer (NBL) formed on the p-type semiconductor substrate; a deep p-type well region (DPW) formed on the first NBL; a P+ base region and an N+ collector region electrically connected to an anode electrode; and an N+ emitter region electrically connected to the source region through an emitter electrode.

The high voltage may be 600V or more.

The low voltage may be 30v or below.

The semiconductor device may further include a body SCR, formed in the gate region, including a highly doped p-type body region (P+ body region) and a highly doped n-type body region (N+ body region), and the body SCR is electrically connected to the ground voltage.

The first PNP guard ring and the second PNP guard ring may be formed to surround the PN diode.

Other features and aspects will be apparent from the following detailed description, the drawings, and the claims.

### BRIEF DESCRIPTION OF DRAWINGS

FIG. 1 illustrates a circuit view of a high-voltage integrated circuit according to one embodiment.

FIG. 2 illustrates a plane view of a high-voltage semiconductor device with an ESD self-protection structure according to one embodiment of the present disclosure.

FIG. 3 illustrates a cross-sectional view of a high-voltage semiconductor device with an ESD self-protection structure according to one embodiment of the present disclosure.

FIG. 4 illustrates a cross-sectional view of a high-voltage semiconductor device including a metal interconnection according to one embodiment of the present disclosure.

FIG. 5 illustrates a cross-sectional view showing an ESD's current path according to one embodiment of the present disclosure.

FIG. 6 illustrates a cross-sectional view showing an ESD's current path according to another embodiment of the present disclosure.

FIG. 7 illustrates a simulation result for a reference structure to which SCR is not applied according to one embodiment.

FIG. 8 illustrates a simulation result for a reference structure to which one embodiment is applied.

FIG. 9 illustrates an impact ionization result obtained by TCAD according to one embodiment of the present disclosure.

FIG. 10 illustrates a TLP curve between the reference HV semiconductor device and the present HV device.

FIG. 11 illustrates a DC breakdown voltage (DCBV) between the reference HV semiconductor device and the present HV device.

FIG. 12 illustrates a cross-sectional view of a high-voltage semiconductor device with enhanced ESD protection function according to another embodiment of the present disclosure.

FIG. 13 illustrates a cross-sectional view of a high-voltage semiconductor device including a metal interconnection according to another embodiment of the present disclosure.

FIG. 14 illustrates a cross-sectional view showing an ESD's current path according to another embodiment of the present disclosure.

FIG. 15 illustrates a cross-sectional view showing an ESD's current path according to another embodiment of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

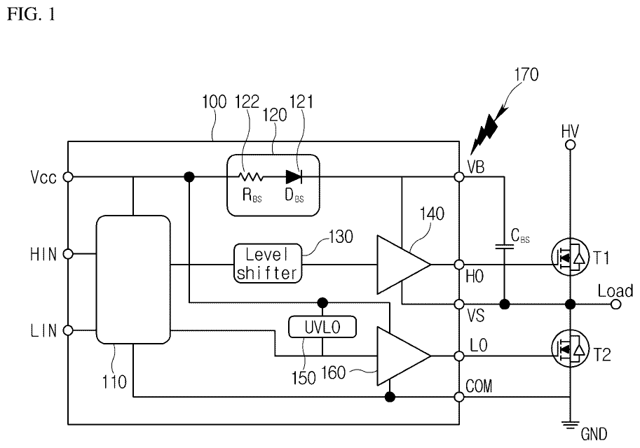

FIG. 1 illustrates a circuit view of a high-voltage integrated circuit according to one embodiment.

The high-voltage integrated circuit 100 shown in FIG. 1 may be a gate driver that provides a gate control signal to switching elements T1 and T2 based on external control.

Referring to FIG. 1, the high-voltage integrated circuit 100 may include a controller 110 configured to provide a gate control signal to the gate of external switching elements T1 and T2, a bootstrap circuit 120, a level shifter 130, a high-side gate driver 140, an under-voltage lockout UVLO 150 and a low-side gate driver 160.

The controller 110 may provide control input to the high-side gate driver 140 and the low-side gate driver 160 for generating a gate control signal of the switching elements T1 and T2 Based on the External Control Signal.

The bootstrap 120 may include a bootstrap diode 121 and a bootstrap resistance 122. According to one embodiment, the bootstrap resistance 122 may be optional. The bootstrap diode 121 may use a PN diode or Schottky diode.

The bootstrap circuit 120 may supply power for the gate control signal to drive a first switching element T1 together with a bootstrap capacitor CBS connected to the outside.

The level shifter 130 may convert a low-side signal into a high-side signal. The level shifter 130 may be formed of a laterally diffused metal oxide semiconductor (LDMOS), an extended drain metal oxide semiconductor (EDMOS), or a diffused metal oxide semiconductor (DMOS). The element formed in the level shifter 130 may have a structure that can withstand high voltage since it has one side connected to a high-voltage region.

According to one embodiment, the high-side gate driver 140 may generate a signal for controlling the first switching element T1, and the low-side gate driver 160 may generate a signal for controlling the second switching element T2.

The UVLO 150 may have a function of detecting when the low-side gate driver 160 is too small to operate and stopping operation. The UVLO 150 may perform the low-side detection and stop operation not only for the voltage related to the low-side gate driver 160 shown in FIG. 1 but also for the input voltage or the voltage related to the high-side gate driver 140.

The first switching element T1 and the second switching element T2 may be an n-type metal oxide semiconductor field effect transistor (NMOSFET) or an insulated gate bipolar transistor (IGBT).

The first switching element T1 may be provided between a high voltage HV and load, a source may be connected to the high voltage HV, and a drain may be connected to the load. A gate of the first switching element T1 may be connected to a high-side output terminal HO of the high-voltage integrated circuit 100, so that the first switching element T1 can be turned on/off by the voltage output from the high-side output terminal HO. The first switching element T1 may output high voltage HV to the load when it is turned on.

The second switching element T2 may be provided between a ground voltage terminal GND and the load, so that the source can be connected to the load, and a drain may be connected to the ground voltage terminal GND. A gate of the second switching element T2 may be connected to a low-side output terminal LO of the high-voltage integrated circuit 100, so that the second switching element T2 can be turned on/off by the voltage output from the low-side output terminal LO. The second switching element T2 may output ground voltage to the output load when it is turned on.

A drain of the first switching element T1 and a source of the second switching element T2 may be connected together to the load.

Referring to FIG. 1, to exchange signals with the outside and receive power desired for an operation, the high-voltage integrated circuit 100 may include a voltage input terminal Vcc, a high side control input terminal HIN, a low side control input terminal LIN, a common ground COM, a high voltage terminal VB, a return voltage terminal VS, a high side output terminal HO and a low side output terminal LO.

The high-voltage integrated circuit 100 may provide the power desired for driving through the voltage input terminal Vcc, and may be connected to an external ground voltage terminal GND through a common ground COM to form a ground that is isolated from the outside.

The high-voltage circuit 100 may output a high-side control signal via a high-side output terminal HO, and the high-side control signal may control the operation of the first switching element T1 in response to a logic signal input through the high-side control input terminal HIN.

The high-side output terminal HO may be connected to a gate of the first switching element T1 and configured to control the switching of the first switching element T1.

The high-voltage integrated circuit 100 may output a low-side control signal via a low-side output terminal LO, and the low-side control signal may control the operation of the second switching element T2 in response to a logical signal input through a low-side control input terminal LIN. The low-side output terminal LO may be connected to a gate of the second switching element T2 and configured to control the switching of the second switching element T2.

The first switching element T1 and the second switching element T2 may be controlled not to be turned on at the same time. For example, while the first switching element T1 is controlled to be turned on, the second switching element T2 may be controlled to be turned off. Alternatively, while the first switching element T1 is controlled to be turned off, the second switching element T2 may be controlled to be turned on.

A bootstrap capacitor CBS may be connected between the high-voltage terminal VB and the high-voltage return voltage terminal VS. Also, the return voltage terminal VS may be connected to load, a drain of the first switching element T1, and a source of the second switching element T2.

A bootstrap diode 121 disposed within the high-voltage integrated circuit 100 and an external bootstrap capacitor CBS may be serially connected to each other. An anode of the bootstrap diode 121 may be connected to a driving power supplied through the voltage input terminal Vcc via a bootstrap resistor 122. One end (e.g., cathode) of the bootstrap capacitor CBS may be connected to a load, a return voltage terminal VS, a drain of the first switching element T1, and a source of the second switching element T2. A cathode of the bootstrap diode 121 and the other end of the bootstrap capacitor CBS may be connected to each other, so that driving power can be supplied to the high-side gate driver 140 at the connected point.

When the second switching element T2 is turned on and the first switching element T1 is turned off, the voltage applied to one end of the bootstrap capacitor CBS becomes ground voltage terminal GND so that a forward voltage can be applied to the bootstrap diode 121 and a forward bias current can flow. Due to the forward bias current, a voltage of a value obtained by subtracting the voltage applied to the bootstrap resistance 122 and the threshold voltage of the bootstrap diode 121 from the driving voltage input through the voltage input terminal Vcc may be applied to the high-voltage terminal VB by the forward bias current. The bootstrap capacitor CBS may be charged by the voltage output from the high-voltage terminal VB.

When the first switching element T1 is turned on and the second switching element T2 is turned off, the voltage applied to one end of the bootstrap capacitor CBS may become a higher voltage HV greater than the driving voltage Vcc, which may cause a reverse voltage to be applied to the bootstrap diode 121 and the bootstrap diode 121 to block the flow of current. At this time, a value obtained by adding the voltage charged in the bootstrap capacitor CBS to the high voltage HV applied to one end of the bootstrap capacitor CBS may be applied to the high-voltage terminal VB. As this voltage is output to the high-side output terminal HO by driving the high-side gate driver 140, the voltage between the source and gate of the first switching element T1 may become a charging voltage for the bootstrap capacitor CBS. Since this charging voltage is greater than the threshold voltage of the first switching element T1, the first switching element T1 may be stably driven.

The high-voltage circuit 100 needs to be designed so as not to damage the internal circuit or semiconductor device when ESD 170 enters the high-voltage terminal VB. The present disclosure proposes a high-voltage semiconductor device that is resistant to ESD and designed to allow high current due to ESD 170 to escape by forming a silicon controlled rectifier (SCR) structure.

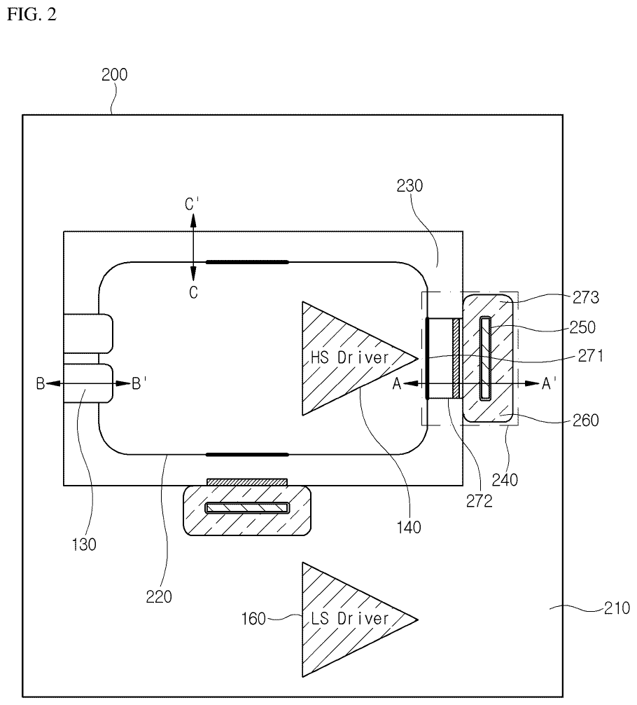

FIG. 2 illustrates a plane view of a high-voltage semiconductor device with an ESD self-protection structure according to one embodiment of the present disclosure.

Referring to FIG. 2, the high-voltage semiconductor device 200 may include a level shifter 130 for changing a signal level between a low-side signal and a high-side signal. The high-voltage semiconductor device 200 may include a low-voltage region 210 having elements that operate at a low voltage, and a high-voltage region 220 having elements operating at a high voltage. For example, the elements operating in the low voltage region may include a controller 110, a UVLO 150, and a low-side gate driver 160. The elements operating in the high voltage region may include a high-side gate driver 140. In an example, the low voltage range may be below 30V and the high voltage range may be up to 1200V.

In addition, a junction termination region 230 for electrically isolating the low voltage region 210 and the high voltage region 220 may be provided. A junction field effect transistor JFET or a lateral double-diffused MOS device LDMOS may be disposed in the function termination region 230. The junction termination region 230 may have a deep trench structure in which an insulating layer is filled.

The high-voltage diode region 240 may include a bootstrap diode 250 configured to pass forward current to a drain region. Here, the bootstrap diode 250 may use a PN diode or a Schottky diode.

The forward current from the bootstrap diode 250 may charge the bootstrap capacitor CBS to a sufficient voltage level. Accordingly, the bootstrap capacitor CBS may provide sufficient voltage to the gate of the first switching element T1 to smoothly operate the first switching element T1. Although FIG. 2 shows only one bootstrap diode 250, a plurality of bootstrap diodes may be formed adjacent to the junction termination region 230.

The high voltage diode region 240 may further include a PNP guard ring 260 surrounding the bootstrap diode 250 to protect the bootstrap diode 250 from high voltage stress.

The PNP guard ring 260 may completely surround the bootstrap diode 250 to protect the bootstrap diode 250 from high voltage stress. Since the bootstrap diode 250 may be vulnerable to high voltage stress, the PNP guard ring 260 may be desired with a large occupation region in the high voltage diode region 240.

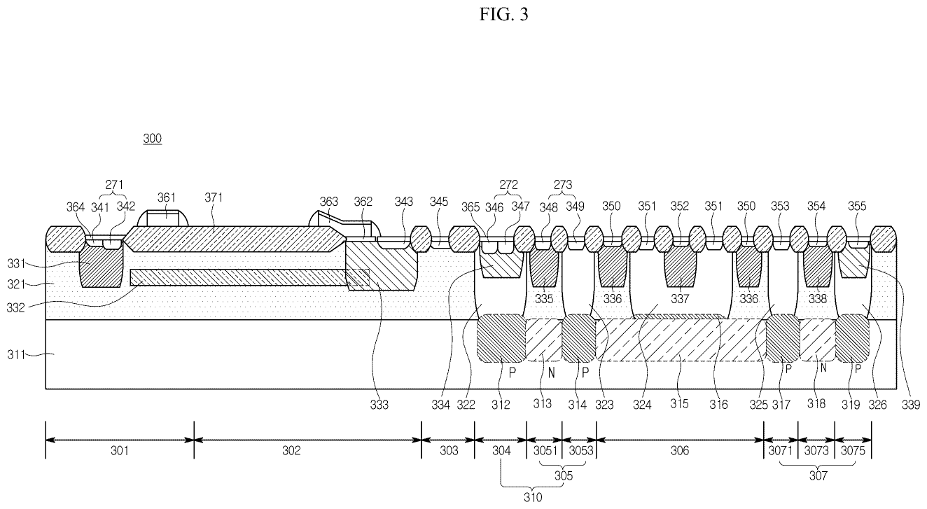

Referring to FIG. 2, the high voltage diode region 240 may include a drain silicon controller rectifier (drain SCR) 271, a first guard ring SCR 272, and a second guard ring SCR 273. The drain SCR, the first guard ring SCR 272, and the second guard ring SCR 273 may be referred to as a first integrated SCR, a second integrated SCR, and a third integrated SCR, respectively. As will be described in detail in FIG. 3, each of the drain SCR 271, the first guard ring SCR 272, and the second guard ring SCR 273 includes a highly doped n-type (N+) region and a highly doped n-type (P+) region. By incorporating several SCR structures or Thyristor structures into the high-voltage diode region 240, a high-voltage semiconductor device 200 resistant to an electrostatic discharge (ESD) stress may be created. The high-voltage semiconductor device 200 may be protected from ESD stress by adding several SCR structures to the high-voltage diode region 240. The SCR structure may comprise PNPN structure. The SCR structure may comprise at least two transistors combining a PNP transistor and an NPN transistor. If a large current, for example, the ESD stress, is applied to the gate of the SCR, the anode and cathode of the SCR become conductive and the SCR is turned on to allow the large current to flow between the anode and cathode. When the large current between the anode and cathode falls below a certain value, the SCR is turned off, and no current flows.

FIG. 3 illustrates a cross-sectional view of a high-voltage semiconductor device with an ESD self-protection structure according to one embodiment of the present disclosure. FIG. 3 illustrates a cross-sectional view showing A-A′ cross section of FIG. 2.

Referring to FIG. 3, the HV semiconductor device 300 with ESD self-protection structure according to one embodiment may include a drain region 301, a gate region 302, a source region 303, a first PNP guard ring 310, a PN diode region 306 and a second PNP guard ring 307.

As shown in FIG. 3, the first PNP guard ring 310 has a cross-sectional area greater than a cross-sectional area of the second PNP guard ring 307. Further, the first PNP guard ring 310 may comprise a first p-type guard ring 304, a first n-type guard ring 3051, and a second p-type guard ring 3052, wherein the second p-type guard ring 3052 is closer to the PN diode 306 than the first p-type guard ring 304. Herein, the NP guard ring 305 may comprise the first n-type guard ring 3051 and the second p-type guard ring 3052, thus the first PNP guard ring 310 may comprise the first p-type guard ring 304 and the NP guard ring 305. The first p-type guard ring 304 has a cross-sectional area greater than a cross-sectional area of the second p-type guard ring 3053.

In the same way, the second PNP guard ring 307 may comprise a third p-type guard ring 3071, a second n-type guard ring 3073, and a fourth p-type guard ring 3075, wherein the third p-type guard ring 3071 is closer to the PN diode 306 than the fourth p-type guard ring 3073. The third p-type guard ring 3071 has a cross-sectional area similar to a cross-sectional area of the fourth p-type guard ring 3075.

The PN diode region 306 may supply forward current to the drain region 301 through the source region 303. The gate region 302 disposed between the drain region 301 and the source region 303 may be used together with the first p-type guard ring 304 when blocking a high voltage current toward the PN diode region 306 in a reverse bias state.

The first PNP guard ring 310 and the second PNP guard ring 307 may be in a form that surrounds the PN diode, and configured to reduce a leakage current that might flow toward the substrate 311. Here, the first PNP guard ring 310 may be disposed between the source region 303 and the PN diode region 306 to allow a large current to flow effectively, when an ESD event occurs.

According to one embodiment, the HV semiconductor device 300 may include a drain SCR 271 formed in the drain region 301, a first guard ring SCR 272 formed in the first p-type guard ring 304, and a second guard ring SCR 273 formed in the NP guard ring 305.

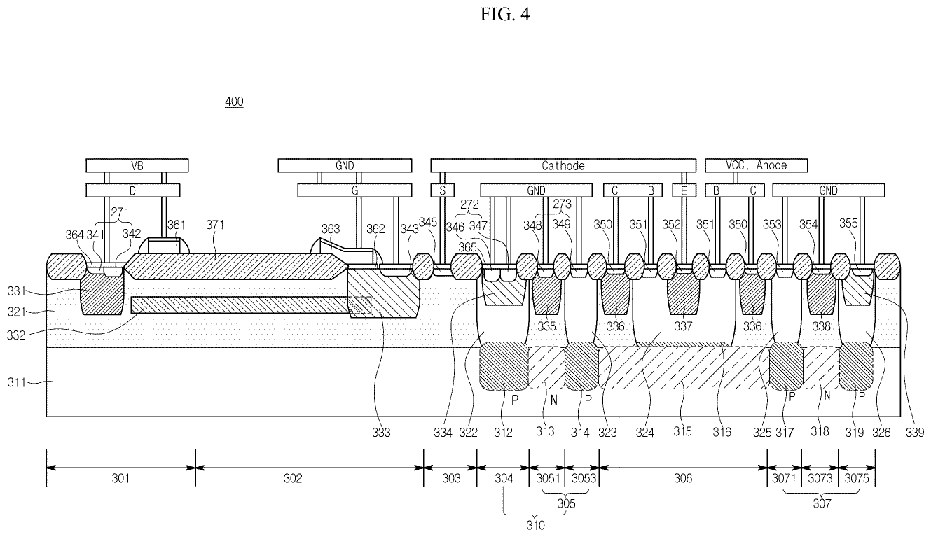

According to one embodiment, a p-type semiconductor substrate (P-sub) 311 is formed in the drain region 301; a high voltage deep n-type well region (HDNW) or n-type epi-layer (N-epi) 321 is formed on the P-sub 311; a first NW 331 is formed in the high voltage deep n-type well region (HDNW) 321; and an N+ drain region 341 and a P+ drain region 342 are formed in contact with each other within the first NW 331. The HDNW 321 may be extended to the first PNP guard ring 310, the PN diode 306, and the second PNP guard ring 307. Here, the N+ drain region 341 and the P+ drain region 342 may correspond to the drain SCR 271. Here, the drain SCR 271 may be connected to a high-voltage terminal VB (e.g., see FIG. 4). In addition, the drain region 301 may further include a Poly-Si field plate 361 formed on a field oxide film (FOX) 371 and a silicide layer 364 formed on the drain SCR 271. The silicide layer 364 may electrically connect the N+ drain region 341 and the P+ drain region 342 to each other.

According to one embodiment, the gate region 302 has a very long horizontal length and thus provides a surface electric field relaxation effect, so it can be called a reduced surface electric field (RESURF). The gate region 302 may include a gate insulating film 362 formed on the P-sub 311; a gate electrode 363 formed on the FOX 371; a p-type body region (P-body) 333 formed to overlap the gate electrode 363; a highly doped P+ body region (P+ body region) 343 formed in the P-body 333; and a p-type top layer (P-TOP) 332 formed between the first NW 331 and the P-body 333. Here, the gate electrode 363, the P-body 333, and the P+ body region 343 may each be connected to a ground voltage terminal GND (e.g., see FIG. 4).

According to one embodiment, the source region 303 may include an N+ source region 345 formed in the HDNW 321. The N+ source region 345 may be disposed between the P-body 333, which is formed to overlap the gate electrode 363, and the first p-type guard ring (P-iso) 304.

According to one embodiment, the first guard ring SCR 272 may be formed in the first p-type guard ring 304, and the second guard ring SCR 273 may be formed in the NP guard ring 305.

As shown in FIG. 3, the first p-type guard ring 304 includes a first p-type buried layer (PBL) 312, a first p-type deep well region (DPW) 322, a first PW region (PW) 334, a first n-type highly doped SCR region (first N+ region) 346, and a first p-type highly doped isolation region (first P+ region) 347. Here, the first N+ region 346 and the first P+ region 347 may correspond to the first guard ring SCR 272. The first p-type guard ring 304 may further include a silicide layer 365 formed on the first N+ region 346 and the first P+ region 347.

According to one embodiment, the first PBL 312 may have a width greater than that of a second NBL 313 or a second PBL 314, because the first N+ region 346 and the first P+ region 347 may be formed in the First p-type guard ring 304 to form the first guard ring SCR 272.

According to one embodiment, the NP guard ring 305 may include the second NBL (NBL) 313 formed on the P-sub 311; a second NW 335 formed on the second NBL 313; the second PBL 314 formed on the P-sub 311; a second DPW 323 formed on the second PBL 314; and a second P+ region 349 formed in the second DPW 323. The second N+ region 348 and the second P+ region 349 formed separately from each other by the FOX 371 may correspond to the second guard ring SCR 273.

According to one embodiment, the first PBL 312, the second NBL 313, and the second PBL 314 may be formed parallel to each other. The first PBL 312 may be formed under the first guard ring SCR 272, and the second NBL 313 and the second PBL 314 may be formed under the second guard ring SCR 273. The first guard ring SCR 272 and the second guard ring SCR 273 may be electrically connected to each other through a contact plug and metal wiring so that both can be connected to ground voltage terminal GND (e.g., see FIG. 4).

According to one embodiment, the PN diode region 306 may include a first NBL 315, a third DPW 324 formed on the first NBL 315; an N+ collector region 350 formed in the third NW 336; a P+ base region 351 formed in the DPW 324; and an N+ emitter region 352 formed in the fourth NW 337. The third NW 336 may enclose the N+ collector region 350. The fourth NW 337 may enclose the N+emitter region 352. A silicide layer may be formed on each of the N+ collector region 350, the P+ base region 351, and the N+ emitter region 352.

According to one embodiment, a thin PBL 316 may be further provided between the first NBL 315 and the third DPW 324 in order to increase the withstand voltage of the PN diode region 306. The thin PBL 316 may be positioned at an upper end of the first NBL 315. The thickness of the thin PBL 316 may be much less than that of the first NBL 315, the first PBL 312, or the second PBL 314.

According to one embodiment, the second PNP guard ring 307 is similar to the first PNP guard ring 310. The second PNP guard ring 307 may include p-type buried layers 317 and 319 and an n-type buried layer 318 formed on the P-sub 311. The second PNP guard ring 307 may further include DPW regions 325 and 326, an NW region 338, a PW region 339, P+ regions 353 and 355, and a third N+ region 354. The P+ regions 353 and 355, and the third N+ region 354 may be separated from each other by the FOX 371.

FIG. 4 illustrates a cross-sectional view of a high-voltage semiconductor device including a metal interconnection according to one embodiment of the present disclosure. FIG. 4 illustrates a cross-sectional view in which a metal interconnect is added to FIG. 3.

Referring to FIG. 4, the drain SCR 271 of the drain region 301 within the HV semiconductor device 400 according to one embodiment may include N+ drain region 341 and P+ drain region 342. The N+ drain region 341 and P+ drain region 342 may be connected to a drain electrode D. A Poly-Si field plate 361 formed on a FOX 371 may also be connected to the drain electrode D. The drain electrode D may be electrically connected to a high-voltage terminal VB. Accordingly, all of the Poly-Si field plate 361, the N+ drain region 341, and the P+ drain region 342 may be electrically connected to the high-voltage terminal VB. A bootstrap capacitor CBS may be charged by the voltage output from the high-voltage terminal VB. A high voltage of 600V or more may be applied to the high-voltage terminal VB.

According to one embodiment, in the gate region 302 of the HV semiconductor device 400, all of the P-body 333, the P+ body region 343, and the gate electrode 363 may be electrically connected to a ground voltage terminal GND through a gate metal G.

According to one embodiment, in the HV semiconductor device 400, the N+ source region 345 of the source region 303 may be electrically connected to a source electrode S. The source electrode S may be electrically connected to a cathode electrode CATHODE. The cathode electrode CATHODE may be electrically connected to an emitter electrode E of the PN diode region 306.

According to one embodiment, in the HV semiconductor device 400, the first guard ring SCR 272 of the first p-type guard ring 304, and the second guard ring SCR 273 of the NP guard ring 305 may both be connected to the ground voltage terminal GND. In addition, the first guard ring SCR 272 and the second guard ring SCR 273 may be electrically connected to a gate metal G. Accordingly, all of the gate electrode 263, the first guard ring SCR 272, and the second guard ring SCR 273 may be connected to the ground voltage terminal GND.

According to one embodiment, when a high voltage is applied to the drain SCR 271, pinch-off may occur between the gate region 302 and the first p-type guard ring 304. In other words, pinch-off may occur between the P-body 333 of the gate region 302 and the DPW 322 of the first p-type guard ring 304. When a high voltage of about 600V or more is applied to the drain electrode D, the flow of current toward the PN diode region 306 may be blocked by the pinch-off phenomenon. The pinch-off must occur to protect the PN diode region 306 from high voltages of 600V or more.

According to one embodiment, in the HV semiconductor device 400, the P+ base region 351 of the PN diode region 306 may be connected to a base electrode B. The N+ collector region 350 may be connected to a collector electrode C. The base electrode B and the collector electrode C may be connected to an anode electrode ANODE where a VCC power source is supplied. Accordingly, the P+ base region 351 and the N+ collector region 350 may both be connected to the anode electrode ANODE.

According to one embodiment, in the HV semiconductor device 400, the N+ emitter region 352 of the PN diode region 306 may be connected to the emitter electrode E. The emitter electrode E may be connected to the cathode electrode CATHODE. Accordingly, it can be said that the N+ emitter region 352 is connected to the N+ source region 345 through the emitter electrode E and the cathode electrode CATHODE.

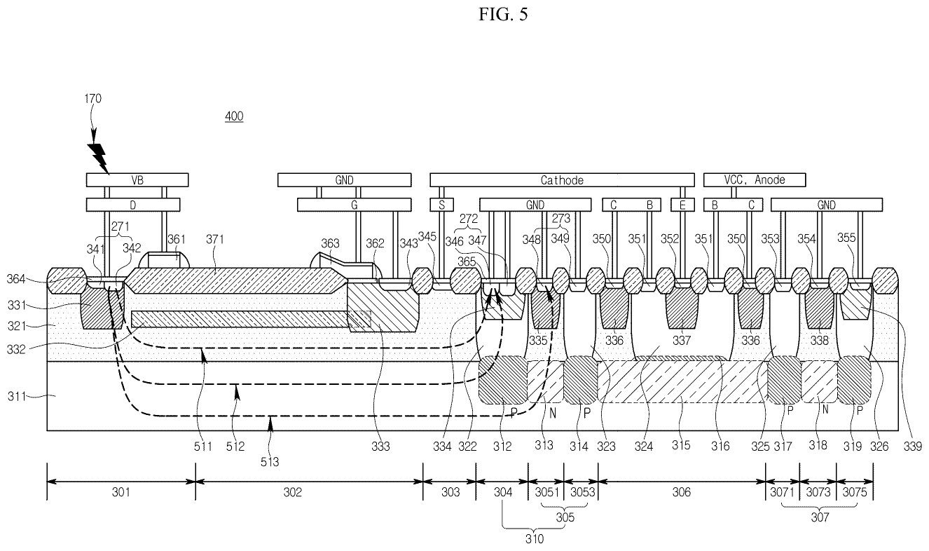

FIG. 5 illustrates a cross-sectional view showing an ESD's current path according to one embodiment of the present disclosure.

Referring to FIG. 5, a plurality of ESD current paths are shown when a very high ESD current 170 flows into the HV semiconductor device 400. A first ESD current path 511, a second ESD current path 512, and a third ESD current path 513 may be formed in the HV semiconductor device 400. The first, second, and third ESD current paths 511, 512, and 513 may start from the high voltage terminal VB to the ground voltage terminal GND of the first p-type guard ring 304 or the ground voltage terminal GND of the NP guard ring 305. All the first, second, and third ESD current paths 511, 512, and 513 belong to PNPN paths. Further, all the first, second, and third ESD current paths 511, 512, and 513 may start from the P+ drain region 342 of the drain SCR 271.

According to one embodiment, in the HV semiconductor device 400, the first ESD current path 511 may comprise the P+ drain region 342 of the drain SCR 271, the HDNW 321, the PW 334, and the first N+ region 346 of the first guard ring SCR 272.

According to one embodiment, in the HV semiconductor device 400, the second ESD current path 512 may comprise the P+ drain region 342 of the drain SCR 271, the HDNW 321, the P-sub 311, and the first N+ region 346 of the first guard ring SCR 272.

According to one embodiment, in the HV semiconductor device 400, the third ESD current path 513 may comprise the P+ drain region 342, the HDNW 321, the P-sub 311, and the second N+ region 348 of the second guard ring SCR 273.

According to one embodiment, in the HV semiconductor device 400, the ESD current may easily flow through the drain SCR 271, the first guard ring SCR 272, and the second guard ring SCR 273.

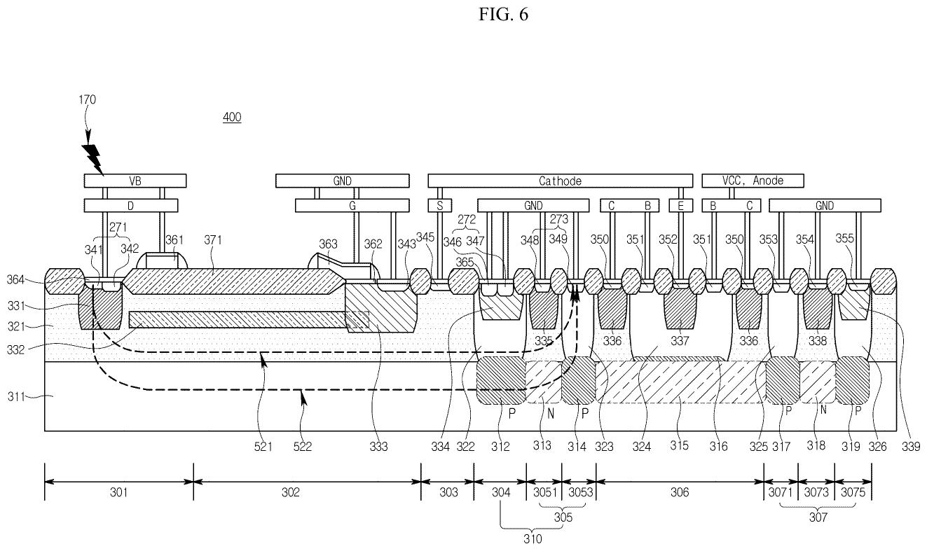

FIG. 6 illustrates a cross-sectional view showing an ESD's current path according to another embodiment of the present disclosure.

Referring to FIG. 6, a plurality of ESD current paths are shown when the very high ESD current 170 flows into the HV semiconductor device 400. A fourth ESD current path 521 and a fifth ESD current path 522 may be formed in the HV semiconductor device 400. The fourth and fifth ESD current paths 521 and 522 may start from the high-voltage terminal VB to the ground voltage terminal GND of the first p-type guard ring 304 or the ground voltage terminal GND of the NP guard ring 305. All the fourth and fifth ESD current paths 521 and 522 belong to NPNP paths. Further, all the fourth and fifth ESD current paths 521 and 522 may start from the N+ drain region 341 of the drain SCR 271.

According to one embodiment, in the HV semiconductor device 400, the fourth ESD current path 521 may comprise the N+ drain region 341 of the drain SCR 271, the DPW 322, the HDNW 321, and the second P+ region 349 of the second guard ring SCR 273.

According to one embodiment, in the HV semiconductor device 400, the fifth ESD current path 522 may comprise the N+ drain region 341 of the drain SCR 271, the P-sub 311, the NBL 313, and the second P+ region 349 of the second guard ring SCR 273.

According to one embodiment, in the HV semiconductor device 400, the ESD current may easily flow through the drain SCR 271, the first guard ring SCR 272, and the second guard ring SCR 273.

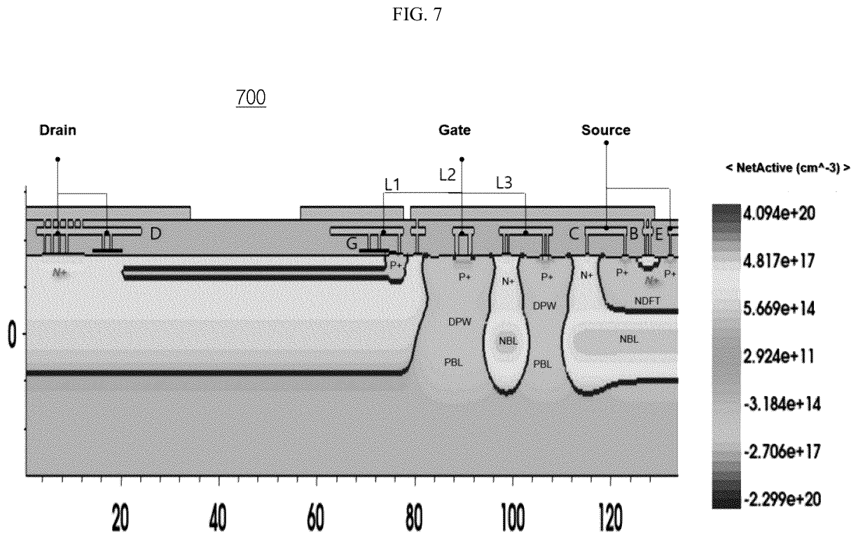

FIG. 7 illustrates a device simulation for a reference HV semiconductor device without SCR.

Referring to FIG. 7, a device simulation for the reference HV semiconductor device 700 is shown. In the reference HV semiconductor device 700, a drain electrode designated “Drain” is electrically connected to the N+ drain region 341. In the drain region, there is no P+ drain region as shown in FIG. 3. In the gate region, three connecting lines L1, L2, and L3 are connected to the gate electrode designated “Gate”. A first connecting line L1 is electrically connected to the gate electrode 363. A second connecting line L2 is electrically connected to the first P+ region 347 in the first p-type guard ring 304. A third connecting line L3 is electrically connected to the second N+ region 348 and the second P+ region 349. A source electrode designated “Source” is electrically connected to the collector region 350 and the base region 351 in the PN diode.

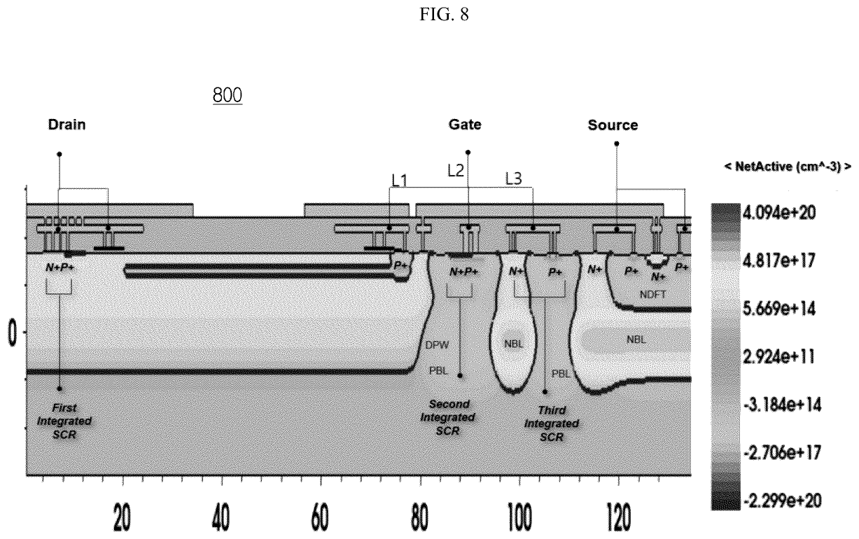

FIG. 8 illustrates a device simulation for the HV semiconductor device with SCR according to one embodiment of the present disclosure.

Referring to FIG. 8, a device simulation for the present HV semiconductor device 800 with an integrated SCR is shown. In the HV semiconductor device 800, a drain electrode designated “Drain” is electrically connected to the N+ drain region 341 and the P+ drain region 342, i.e., the first integrated SCR. Please note that the reference numbers refer to FIG. 4. In the gate region, three connecting lines L1, L2, and L3 are connected to the gate electrode designated “Gate”. A first connecting line L1 is electrically connected to the gate electrode 363. A second connecting line L2 is electrically connected to the first N+ region 346 and the first P+ region 347 in the first p-type guard ring 304, i.e., the second integrated SCR. A third connecting line L3 is electrically connected to the second N+ region 348 and the second P+ region 349, i.e., the third integrated SCR. Herein the first integrated SCR, the second integrated SCR, and the third integrated SCR may be assigned to the drain SCR, the first guard ring SCR 272, and the second guard ring SCR 273, respectively. A source electrode designated “Source” is electrically connected to the collector region 350 and the base region 351 in the PN diode.

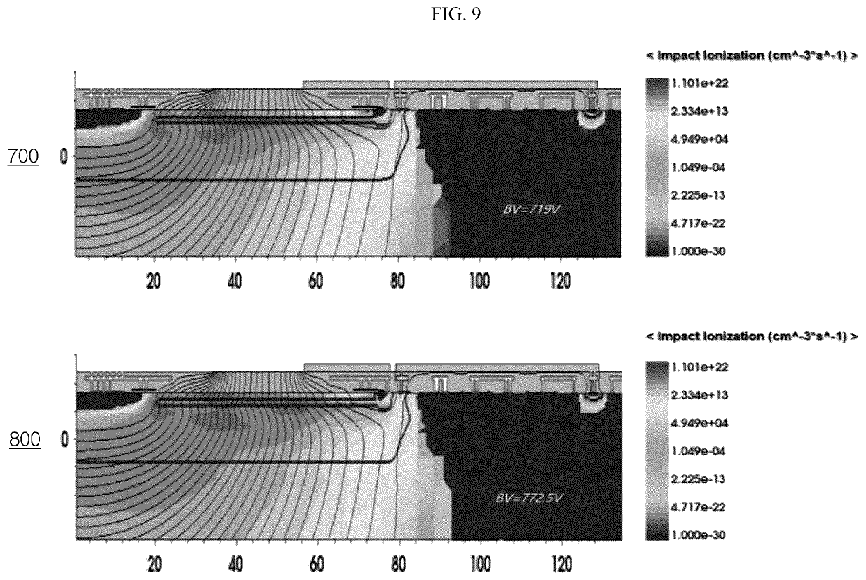

FIG. 9 illustrates an impact ionization result obtained by TCAD according to one embodiment of the present disclosure.

Referring to FIG. 9, impact ionization results are compared of the present HV semiconductor device 800 to the reference HV semiconductor device 700. The impact ionization result may be obtained by changing voltages at the drain electrode designated “Drain”, while the gate electrode designated “Gate” and the source electrode designated “Source” are fixed to a ground voltage. Similar impact ionization results are shown between the present HV semiconductor device 800 and the reference HV semiconductor device 700, however, the breakdown voltages under the reverse bias state are different. For example, the present HV semiconductor device 800 has a value, 772.5V greater than a value, 719V of the reference HV semiconductor device 700.

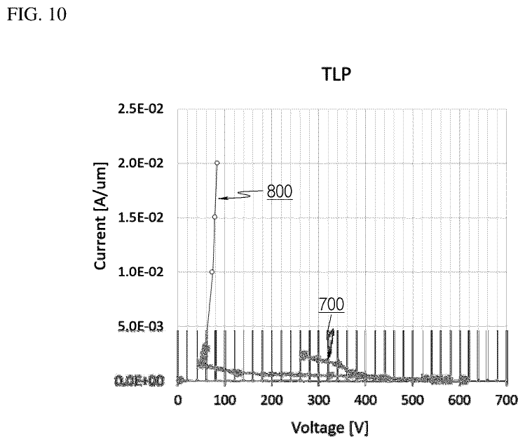

FIG. 10 illustrates a transmission line pulse (TLP) curve between the reference HV semiconductor device and the present HV device.

Referring to FIG. 10, the reference HV semiconductor device 700 shows no holding voltage (Vh) in the TLP curve, although a triggering voltage (Vt1) is similar to that of the present HV semiconductor device 800. On the contrary, the present HV semiconductor device 800 shows a reasonable triggering voltage Vt1 and a stable holding voltage Vh in the TLP curve. The present HV semiconductor device 800 has a better electrical performance than the reference HV semiconductor device 700 in the ESD characteristics.

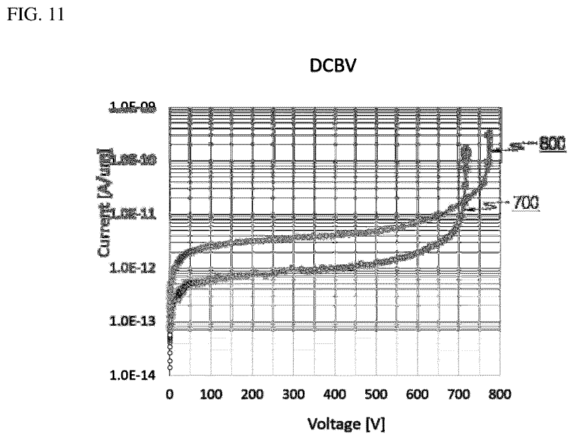

FIG. 11 illustrates a DC breakdown voltage (DCBV) between the reference HV semiconductor device and the present HV device.

Referring to FIG. 11, the reference HV semiconductor device 700 and the present HV semiconductor device 800 have DCBV values of 719V and 772.5V, respectively, and the present HV semiconductor device 800 has a higher DC breakdown voltage (DCBV) than the reference HV semiconductor device 700.

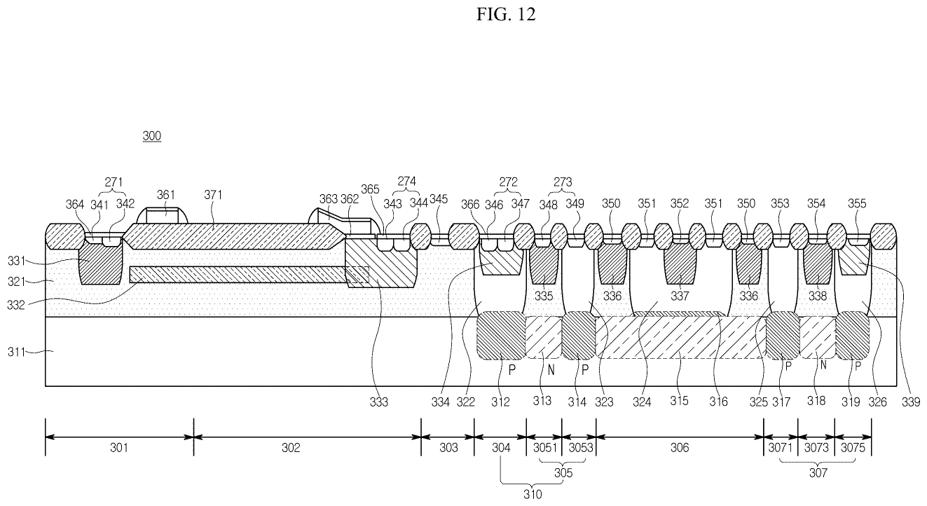

FIG. 12 illustrates a cross-sectional view of a high-voltage semiconductor device with enhanced ESD protection function according to another embodiment of the present disclosure. FIG. 12 is a cross-sectional view showing A-A′ cross-section of FIG. 2.

Referring to FIG. 12, the HV semiconductor device 300 with ESD self-protection structure according to one embodiment may include a drain region 301, a gate region 302, a source region 303, a first PNP guard ring 310 comprising a first p-type guard ring 304 and a NP guard ring 305, a PN diode 306 and a second PNP guard ring 307.

As shown in FIG. 12, the first PNP guard ring 310 has a cross-sectional area greater than a cross-sectional area of the second PNP guard ring 307. Further, the first PNP guard ring 310 may comprise a first p-type guard ring 304, a first n-type guard ring 3051, and a second p-type guard ring 3053, wherein the second p-type guard ring 3053 is closer to the PN diode 306 than the first p-type guard ring 304. Herein, the NP guard ring 305 may comprise the first n-type guard ring 3051 and the second p-type guard ring 3053, thus the first PNP guard ring 310 may comprise the first p-type guard ring 304 and the NP guard ring 305. The first p-type guard ring 304 has a cross-sectional area greater than a cross-sectional area of the second p-type guard ring 3053.

In the same way, the second PNP guard ring 307 may comprise a third p-type guard ring 3071, a second n-type guard ring 3073, and a fourth p-type guard ring 3075, wherein the third p-type guard ring 3071 is closer to the PN diode 306 than the fourth p-type guard ring 3075. The third p-type guard ring 3071 has a cross-sectional area similar to a cross-sectional area of the fourth p-type guard ring 3075.

As shown in FIG. 12, the PN diode 306 may supply forward current to the drain region 301 through the source region 303. The gate region 302 disposed between the drain region 301 and the source region 303 may be used together with the first p-type guard ring 304 when blocking a high voltage stress toward the PN diode 306. The first PNP guard ring 310 and the second PNP guard ring 307 may be formed to surround the PN diode 306, and configured to block leakage current that might flow toward the P-sub 311.

According to one embodiment, the HV semiconductor device 300 may include a drain SCR 271 formed in the drain region 301, a first guard ring SCR 272 formed in the first p-type guard ring 304, and a second guard ring SCR 273 formed in the NP guard ring 305.

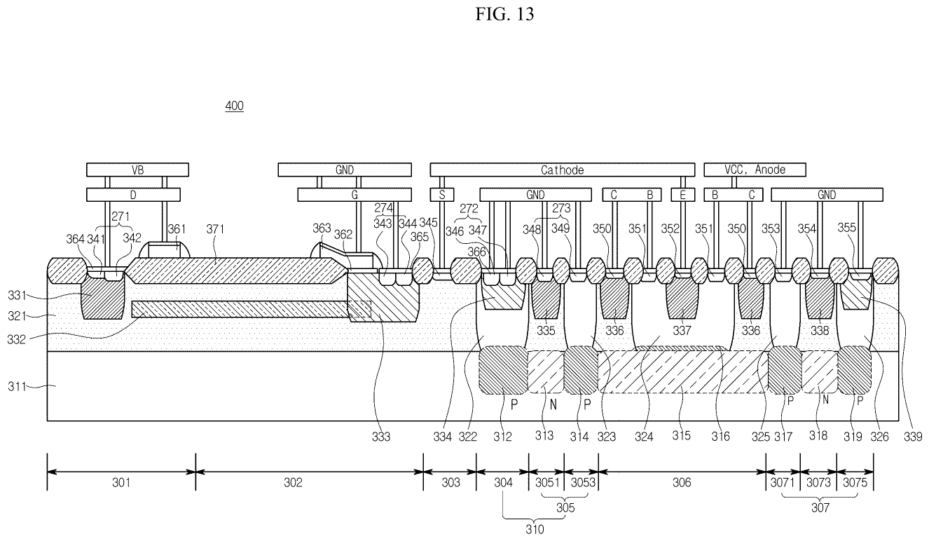

According to one embodiment, the drain region 301 may include a P-sub 311; an HDNW 321 formed on the P-sub 311; a first NW 331 formed in the HDNW 321; an N+ drain region 341, and a P+ drain region 342 formed in contact with each other within the NW 331. Here, the N+ drain region 341 and the P+ drain region 342 may correspond to the drain SCR 271. Here, the drain SCR 271 may be connected to a high-voltage terminal VB (e.g., see FIG. 13). In addition, the drain region 301 may further include a filed plate 361 formed on a FOX 371 and a silicide layer 364 formed on the drain SCR 271. The silicide layer 364 may electrically connect the N+ drain region 341 and the P+ drain region 342 to each other.

According to one embodiment, the gate region 302 has a very long horizontal length and thus provides a surface electric field relaxation effect, so it can be called a reduced surface electric field RESURF region. The gate region 302 may include a gate insulating film 362 formed on the P-sub 311; a gate electrode 363 formed on the FOX 371; a P-body 333 formed to overlap the gate electrode 363; a body SCR 274 comprising a P+ body region 343 and a N+ body region 344 formed in the P-body 333; and a P-TOP 332 formed between the first NW 331 and the P-body 333 to be helpful to electric field relaxation. Here, the gate electrode 363, the P-body 333, and the body SCR 274 comprising the P+ body region 343 and the N+ body region 344 may each be connected to a ground voltage terminal GND (e.g., see FIG. 13). Here, P+ body region and N+ body region can be interchanged. For example, a N+ body region 343 and a P+ body region 344 may be formed in the P-body 333, instead of the P+ body region 343 and the N+ body region 344.

According to one embodiment, the source region 303 may include an N+ source region 345 formed in the HDNW 321. The N+ source region 345 may be disposed between the P-body 333, which is formed to overlap the gate electrode 363, and the first p-type guard ring 304.

According to one embodiment, the first guard ring SCR 272 may be formed in the first p-type guard ring 304, and the second guard ring SCR 273 may be formed in the NP guard ring 305.

According to one embodiment, the first p-type guard ring 304 includes a first PBL 312, a first DPW 322, a first PW 334, a first N+ region 346, and a first P+ region 347. Here, the first N+ region 346 and the first P+ region 347 may correspond to the first guard ring SCR 272. The P-isolation region 304 may further include a silicide layer 365 formed on the first N+ region 346 and the first P+ region 347.

According to one embodiment, the NP guard ring 305 may include a second NBL 313 and a second NW 335 formed on the P-sub 311; a second P+ region 349 formed in the second DPW 323. The second N+ region 348 and the second P+ region 349 formed separately from each other by the FOX 371 may correspond to the second guard ring SCR 273.

According to one embodiment, the first PBL 312, the second NBL 313, and the second PBL 314 may be formed parallel to each other. The first PBL 12 may be formed under the first guard ring SCR 272, and the second NBL 313 and the second PBL 314 may be formed under the second guard ring SCR 273. The first guard ring SCR 272 and the second guard ring SCR 273 may be electrically connected to each other through a contact plug and metal wiring so that both can be connected to ground voltage terminal GND (e.g., see FIG. 13).

According to one embodiment, the PN diode 306 may include a thin PBL 316, a diode DPW 324 formed on the first NBL 315; a N+ collector region 350 formed in the cathode NW 336; a P+ base region 351 formed in the diode DPW 324; and an N+emitter region 352 formed in the emitter NW 337. The PN diode 306 may include the cathode NW 336 and the emitter NW 337 surrounding the N+ collector region 350 and the N+emitter region 352, respectively. A silicide layer may be formed on each of the N+ collector region 350, the P+ base region 351, and the N+emitter region 352.

According to one embodiment, in order to increase the withstand voltage of the PN diode 306, a thin PBL 316 may be further provided between the first NBL 315 and the diode DPW 324. The thin PBL 316 may be positioned at an upper end of the first NBL 315. The thickness of the thin PBL 316 may be much less than that of the first NBL 315.

According to one embodiment, the second PNP guard ring 307 has a PNP guard ring shape. The second PNP guard ring 307 may include a third PBL 317 formed on the P-sub 311; a third DPW 325; a third P+ region 353; a third NBL 318 formed on the P-sub 311 as N-type guard ring N; a third NW 338; a third N+ region 354; a fourth PBL 319 formed on the P-sub 311 as first p-type guard ring P; and a fourth DPW 326; and a fourth P+ region 355 formed in the PW 339. The third P+ region 353, the third N+ region 354, and the fourth P+ region 355 may be separated from each other by a FOX 371.

FIG. 13 illustrates a cross-sectional view of a high-voltage semiconductor device including a metal interconnection according to another embodiment of the present disclosure. FIG. 13 is a cross-sectional view in which a metal interconnect is added to FIG. 12.

Referring to FIG. 13, a drain SCR 271 of a drain region 301 within the HV semiconductor device 400, according to one embodiment, may include first N-type and P-type high-concentration doping regions 341 and 342. The first N-type and P-type high-concentration regions 341 and 342 may be connected to a drain electrode D. A field plate 361 formed on a FOX 371 may also be connected to a drain electrode D. The drain electrode D may be electrically connected to a high-voltage terminal VB. Accordingly, all of the field plate 361, the N+ drain region 341, and P+ drain region 342 may be electrically connected to the high-voltage terminal VB. A bootstrap capacitor CBS may be charged by the voltage output from the high-voltage terminal VB. A high voltage of 600V or more may be applied to the high-voltage terminal VB.

According to one embodiment, in the gate region 302 of the HV semiconductor device 400, all of the P-body 333, the gate electrode 363, and the body SCR 274 comprising the P+ body region 343 and the N+ body region 344 may be electrically connected to a ground voltage terminal GND through a gate metal G.

According to one embodiment, in the HV semiconductor device 400, the N+ source region 345 of a source region 303 may be electrically connected to a source electrode S. The source electrode S may be electrically connected to a cathode electrode CATHODE. The cathode electrode CATHODE may be electrically connected to an emitter electrode E of a PN diode 306.

According to one embodiment, in the HV semiconductor device 400, a first guard ring SCR 272 of a first p-type guard ring 304 and a second guard ring SCR 273 of an NP guard ring 305 may both be connected to the ground voltage terminal GND. In addition, a first guard ring SCR 272 and a second guard ring SCR 273 may be electrically connected to a gate metal G. Accordingly, all of the gate electrode 263, the first guard ring SCR 272, and the second guard ring SCR 273 may be connected to the ground voltage terminal GND.

According to one embodiment, when a high voltage is applied to the drain SCR 271, pinch-off may occur between the gate region 302 and the first p-type guard ring 304. In other words, pinch-off may occur between the P-body 333 of the gate region 302 and the first DPW 322 of the first p-type guard ring 304. When a high voltage of about 600V or more is applied to the drain electrode D, the flow of current toward the PN diode 306 may be blocked by the pinch-off phenomenon. The pinch-off must occur to protect the PN diode 306 from high voltages of 600V or more.

According to one embodiment, in the HV semiconductor device 400, the P+ base region 351 of the PN diode 306 may be connected to a base electrode B. The N+ collector region 350 may be connected to a collector electrode C. The base electrode B and the collector electrode C may be connected to an anode electrode ANODE where a VCC power source is supplied. Accordingly, the P+ base region 351 and the N+ collector region 350 may both be connected to the anode electrode ANODE.

According to one embodiment, in the HV semiconductor device 400, the N+ emitter region 352 of the PN diode 306 may be connected to an emitter electrode E. The emitter electrode E may be connected to a cathode electrode CATHODE. Accordingly, it can be said that the N+ emitter region 352 is connected to the N+ source region 345 through the emitter electrode E and the cathode electrode CATHODE.

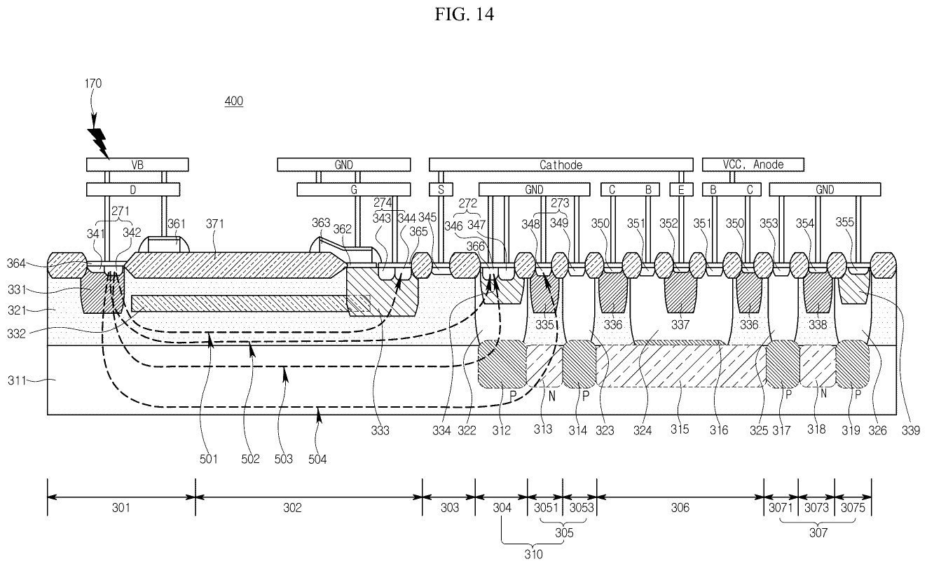

FIG. 14 illustrates a cross-sectional view showing an ESD's current path according to another embodiment of the present disclosure.

FIG. 14 shows that the very high ESD current flows into the P+ drain region 342 of the drain SCR 271. The high ESD current flows into the ground voltage terminal GND of the gate region 302, the first p-type guard ring 304 and the NP guard ring 305 along first to fourth ESD current paths 501, 502, 503, and 504 without damaging the HV semiconductor device 400. The first to fourth ESD current paths 501, 502, 503, and 504 all refer to PNPN paths.

According to one embodiment, in the HV semiconductor device 400, the first ESD current path 501 passes through the P+ drain region 342 of the drain SCR 271, the HDNW 321, the P-body 333, and the N+ body region 344 of the body SCR 274.

According to one embodiment, in the HV semiconductor device 400, the second ESD current path 502 passes through the P+ drain region 342 of the drain SCR 271, the HDNW 321 and the P-type well region, and the first N+ region 346 of the second guard ring SCR 273.

According to one embodiment, in the HV semiconductor device 400, the third ESD current path 503 passes through the P+ drain region 342 of the drain SCR 271, the HDNW 321, the P-sub 311, and the first N+ region 346 of the second guard ring SCR 273.

According to one embodiment, in the HV semiconductor device 400, the four ESD current path 504 passes through the P+ drain region 342 of the drain SCR 271, the HDNW 321, the P-sub 311, and the second N+ region 348 of the second guard ring SCR 273.

According to one embodiment, in the HV semiconductor device 400, since the first ESD current path 501 is shorter than the second to fourth ESD current paths 502, 503, and 504, there is a high probability that the very high ESD current will be discharged through the first ESD current path 501.

According to one embodiment, the HV semiconductor device 400 may be formed to allow high current due to the ESD to flow out well by using the drain SCR 271, the first guard ring SCR 272 and the second guard ring SCR 273, and the body SCR 274 thereby becoming a device strongly resistant to ESD.

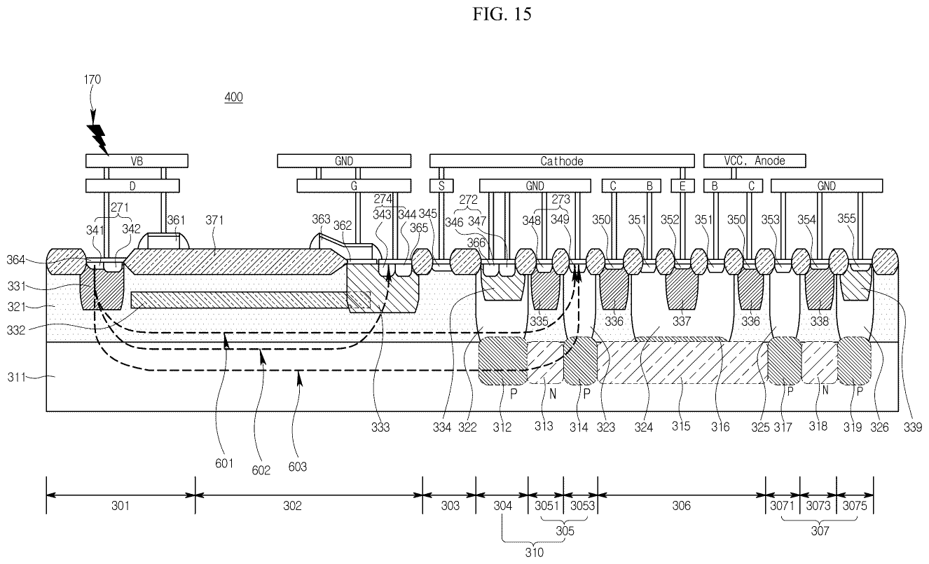

FIG. 15 illustrates a cross-sectional view showing an ESD's current path according to another embodiment of the present disclosure.

Referring to FIG. 15, it shows that the very high ESD current flows into the N+ drain region 341 of the drain SCR 271. The high ESD current may discharge into the gate region 302, the first p-type guard ring 304, and the ground voltage terminal GND of the NP guard ring 305, along fifth to seventh ESD current paths 601, 602, and 603 without damaging the HV semiconductor device 400. The fifth to seventh ESD current paths 601, 602 and 603 all refer to NPNP paths.

According to one embodiment, in the HV semiconductor device 400, the fifth ESD current path 601 passes through the N+ drain region 341 of the drain SCR 271, the first DPW 322, the HDNW 321, and the second P+ region 349 of the second guard ring SCR 273.

According to one embodiment, in the HV semiconductor device 400, the sixth ESD current path 602 passes through the N+ drain region 341 of the drain SCR 271, the P-sub 311, the HDNW 321, and the N+ body region 344 of the body SCR 274.

According to one embodiment, in the HV semiconductor device 400, the seventh ESD current path 603 passes through the N+ drain region 341 of the drain SCR 271, the P-sub 311, the second NBL 313, and the second P+ region 349 of the second guard ring SCR 273.

Since the sixth ESD current path 601 is shorter than the fifth ESD current path 601 or the seventh ESD current path 603, there is a high probability that the very high ESD current will be discharged through the sixth ESD current path 601.

According to one embodiment, the HV semiconductor device 400 may be formed to allow high current due to the ESD to flow out well by using the drain SCR 271 to second guard ring SCR 273, thereby becoming a device strongly resistant to ESD.

Accordingly, one object of the present disclosure is to solve the above-noted disadvantages of the prior art, and embodiments of the present disclosure may provide a HV semiconductor device with ESD self-protection structure to withstand the very high ESD current.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a PN diode formed on a p-type semiconductor substrate;
a drain region and a source region formed on the p-type semiconductor substrate;
a gate region formed between the drain region and the source region;
a first p-type guard ring and a NP guard ring surrounding the PN diode, the NP guard ring comprising a n-type guard ring and a second p-type guard ring;
a drain Silicon Controlled Rectified (SCR) formed in the drain region and comprising a highly-doped n-type drain region (N+ drain region) and a highly-doped p-type drain region (P+ drain region), the drain SCR electrically connected to a high voltage;
a first guard ring SCR formed in the first p-type guard ring and comprising a first highly doped n-type region (first N+ region) and a first highly doped p-type region (first P+ region); and
a second guard ring SCR formed in the NP guard ring and comprising a second N+ region and a second P+ region,
wherein the first guard ring SCR and the second guard ring SCR are electrically connected to a ground voltage.

2. The semiconductor device of claim 1, wherein the high voltage is 600V or more.

3. The semiconductor device of claim 1, wherein the first p-type guard ring has a cross-sectional area greater than a cross-sectional area of the second p-type guard ring.

4. The semiconductor device of claim 1, wherein the PN diode comprises:
a first n-type buried layer (NBL) formed on the p-type semiconductor substrate;
a deep p-type well region (DPW) formed on the first NBL;
a P+ base region and an N+ collector region electrically connected to an anode electrode; and
an N+ emitter region electrically connected to the source region through an emitter electrode.

5. The semiconductor device of claim 1, further comprising:
an n-type semiconductor region formed on the p-type semiconductor substrate;
a first n-type well region (NW) enclosing the drain SCR; and
a field plate electrically connected to the drain SCR and formed on a field oxide film (FOX);
a p-type top layer (P-TOP) formed in the n-type semiconductor region;
a p-type body region (P-body) electrically connected to the P-TOP;
a highly doped p-type body region (P+ body region) formed in the P-body; and
a gate electrode overlapped with the P-body; and
a highly doped n-type source region (N+ source region) formed in the n-type semiconductor region.

6. The semiconductor device of claim 1, further comprising:
a first p-type buried layer (first PBL) formed in the first p-type guard ring and formed below the first N+ region and the first P+ region;
a second NBL formed in the NP guard ring and formed below the second N+ region; and
a second PBL formed in the NP guard ring and formed below the second P+ region,
wherein the second N+ region and the second P+ region are formed separately from each other by a field oxide film (FOX).

7. The semiconductor device of claim 1, further comprising:
a body SCR formed in the gate region and comprising a highly doped p-type body region (P+ body region) and a highly doped n-type body region (N+ body region), the body SCR electrically connected to the ground voltage.

8. The semiconductor device of claim 7, wherein the P+ body region is formed closer to the drain region than the N+ body region.

9. A semiconductor device comprising:
a PN diode formed on a p-type semiconductor substrate;
a drain region and a source region formed on the p-type semiconductor substrate;
a gate region formed between the drain region and the source region;
a first p-type guard ring and a NP guard ring surrounding the PN diode, the NP guard ring comprising a n-type guard ring and a second p-type guard ring;
a drain Silicon Controlled Rectified (SCR) formed in the drain region and comprising a highly-doped n-type drain region (N+ drain region) and a highly-doped p-type drain region (P+ drain region), the drain SCR electrically connected to a high voltage;
a body SCR formed in the gate region and comprising a highly-doped p-type body region (P+ body region) and a highly-doped n-type body region (N+ body region), the body SCR electrically connected to a ground voltage;
a first guard ring SCR formed in the first p-type guard ring and comprising a first highly doped n-type region (first N+ region) and a first highly doped p-type region (first P+ region); and
a second guard ring SCR formed in the NP guard ring and comprising a second N+ region and a second P+ region,
wherein the first guard ring SCR and the second guard ring SCR are electrically connected to the ground voltage.

10. The semiconductor device of claim 9, wherein the high voltage is 600V or more.

11. The semiconductor device of claim 9, wherein the first p-type guard ring has a cross-sectional area greater than a cross-sectional area of the second p-type guard ring.

12. The semiconductor device of claim 9, wherein the P+ body region is formed closer to the drain region than the N+ body region.

13. The semiconductor device of claim 9, wherein the PN diode comprises:
a first n-type buried layer (NBL) formed on the p-type semiconductor substrate;
a deep p-type well region (DPW) formed on the first NBL;
a P+ base region and an N+ collector region electrically connected to an anode electrode; and
an N+ emitter region electrically connected to the source region through an emitter electrode.

14. The semiconductor device of claim 9, further comprising:
an n-type semiconductor region formed on the p-type semiconductor substrate;
a first n-type well region (NW) enclosing the drain SCR; and
a field plate electrically connected to the drain SCR and formed on a field oxide film (FOX);
a p-type top layer (P-TOP) formed in the n-type semiconductor region;
a p-type body region (P-body) electrically connected to the P-TOP;
a highly doped p-type body region (P+ body region) formed in the P-body; and
a gate electrode overlapped with the P-body; and
a highly doped n-type source region (N+ source region) formed in the n-type semiconductor region.

15. The semiconductor device of claim 9, further comprising:
a first p-type buried layer (first PBL) formed in the first p-type guard ring and formed below the first N+ region and the first P+ region;
a second NBL formed in the NP guard ring and formed below the second N+ region; and
a second PBL formed in the NP guard ring and formed below the second P+ region,
wherein the second N+ region and the second P+ region are formed separately from each other by a field oxide film (FOX).

16. A semiconductor device configured to operate in low and high voltages, comprising:
a drain region, a gate region, a source region, a first PNP guard ring, a PN diode, and a second PNP guard ring sequentially formed in order on a p-type semiconductor substrate, the PN diode comprising:
a first n-type buried layer (NBL) formed on the p-type semiconductor substrate;
a deep p-type well region (DPW) formed on the first NBL;
a P+ base region and an N+ collector region electrically connected to an anode electrode; and
an N+ emitter region electrically connected to the source region through an emitter electrode;
a drain Silicon Controlled Rectified (SCR), formed in the drain region, comprising a highly-doped n-type drain region (N+ drain region) and a highly-doped p-type drain region (P+ drain region), the drain SCR electrically connected to a high voltage;
a first guard ring SCR, formed in the first PNP guard ring, comprising a first highly doped n-type region (first N+ region) and a first highly doped p-type region (first P+ region); and
a second guard ring SCR formed, adjacent to the first guard ring SCR, in the first PNP guard ring, the second guard ring SCR comprising a second N+ region and a second P+ region,
wherein the first guard ring SCR and the second guard ring SCR are electrically connected to a ground voltage.

17. The semiconductor device of claim 16, wherein the high voltage is 600V or more.

18. The semiconductor device of claim 16, wherein the low voltage is 30v or below.

19. The semiconductor device of claim 16, further comprising:
a body SCR, formed in the gate region, comprising a highly doped p-type body region (P+ body region) and a highly doped n-type body region (N+ body region), and the body SCR is electrically connected to the ground voltage.

20. The semiconductor device of claim 16, wherein the first PNP guard ring and the second PNP guard ring are formed to surround the PN diode.
